(19) United States
(12) Patent Application Publication
(10) Pub. No.: US 2014/0370651 A1
(43) Pub. Date: Dec. 18, 2014

(54) METHOD OF MANUFACTURING SEMICONDUCTOR DEVICE

(71) Applicant: SANYO ELECTRIC CO., LTD., Osaka (JP)

(72) Inventors: Takuo TOCHIHARA, Osaka (JP); Naoya SOTANI, Hyogo (JP); Mitsuaki MORIGAMI, Osaka (JP)

(21) Appl. No.: 14/476,833

(22) Filed: Sep. 4, 2014

Related U.S. Application Data
(63) Continuation of application No. PCT/JP2013/053980, filed on Feb. 19, 2013.

(30) Foreign Application Priority Data
Mar. 8, 2012 (JP) 2012-051757

(51) Int. Cl. H01L 31/0224; H01L 31/18

(52) U.S. Cl. CPC H01L 31/022441; H01L 31/18
USPC 438/98

(57) ABSTRACT

A semiconductor device includes a substrate made of a semiconductor material, an n-type semiconductor layer arranged on a portion of one principal surface of the substrate, and a p-type semiconductor layer arranged on a portion of the one principal surface of the substrate, the portion not provided with the n-type semiconductor layer. The n-type semiconductor layer includes a portion located right above the p-type semiconductor layer.

### CROSS REFERENCE TO RELATED APPLICATIONS

This application is a continuation application of International Application No. PCT/JP2013/053980, filed on Feb. 19, 2013, entitled “SEMICONDUCTOR DEVICE MANUFACTURING METHOD”, which claims priority based on Article 8 of Patent Cooperation Treaty from prior Japanese Patent Applications No. 2012-051757, filed on Mar. 8, 2012, the entire contents of which are incorporated herein by reference.

### BACKGROUND

The invention relates to a method of manufacturing a semiconductor device.

Heretofore, back contact solar cells have been known as solar cells capable of achieving improved photoelectric conversion efficiency. For example, Patent Document 1 discloses a back contact solar cell including a substrate made of a semiconductor material, and a p-type semiconductor layer and an n-type semiconductor layer provided on one principal surface of the substrate.

Patent Document 1: Japanese Patent Application Publication No. 2011-44749

### SUMMARY OF THE INVENTION

The manufacturing of a semiconductor device including a p-type semiconductor layer and an n-type semiconductor layer provided on one principal surface of a substrate made of a semiconductor material like the solar cell described in Patent Document 1 requires, for example, many patterning processes such as processes of patterning the p-type semiconductor layer and the n-type semiconductor layer. Accordingly, such semiconductor device has a problem of complicated manufacturing processes.

One aspect of the invention provides a method capable of easily manufacturing a semiconductor device.

A method of manufacturing a semiconductor device according to the embodiment involves a p-type semiconductor layer formation process of forming a p-type semiconductor layer on a portion of one principal surface of a substrate made of a semiconductor material. An n-type semiconductor layer is formed on the one principal surface of the substrate and also on the p-type semiconductor layer. At least part of a portion of the n-type semiconductor layer located above the p-type semiconductor layer is etched by using an alkaline etchant.

A semiconductor device according to the embodiment includes a substrate made of a semiconductor material, an n-type semiconductor layer and a p-type semiconductor layer. The n-type semiconductor layer is arranged on a portion of one principal surface of the substrate. The p-type semiconductor layer is arranged on a portion of the one principal surface of the substrate, the portion not provided with the n-type semiconductor layer. The n-type semiconductor layer includes a portion located right above the p-type semiconductor layer.

The embodiments above provide a method of easily manufacturing a semiconductor device.

### BRIEF DESCRIPTION OF THE DRAWINGS

FIG. 1 is a schematic plan view of a solar cell according to an embodiment.

FIG. 2 is a schematic cross-sectional view taken along a line II-II part in FIG. 1.

FIG. 3 is a schematic cross-sectional view for explaining a method of manufacturing a solar cell according to the embodiment.

FIG. 4 is a schematic cross-sectional view for explaining the method of manufacturing a solar cell according to the embodiment.

FIG. 5 is a schematic cross-sectional view for explaining the method of manufacturing a solar cell according to the embodiment.

FIG. 6 is a schematic cross-sectional view for explaining the method of manufacturing a solar cell according to the embodiment.

### EMBODIMENTS

Hereinafter, examples of preferred embodiments are described. It should be noted that the following embodiments are provided just for illustrative purposes. The invention should not be limited at all to the following embodiment.

In the drawings referred to in the embodiments and other part, components having substantially the same function are referred to with the same reference numeral. In addition, the drawings referred to in the embodiments and other part are illustrated schematically, and the dimensional ratio and the like of objects depicted in the drawings are different from those of actual objects in some cases. The dimensional ratio and the like of objects are different among the drawings in some cases. The specific dimensional ratio and the like of objects should be determined with the following description taken into consideration.

### (Configuration of Solar Cell 1)

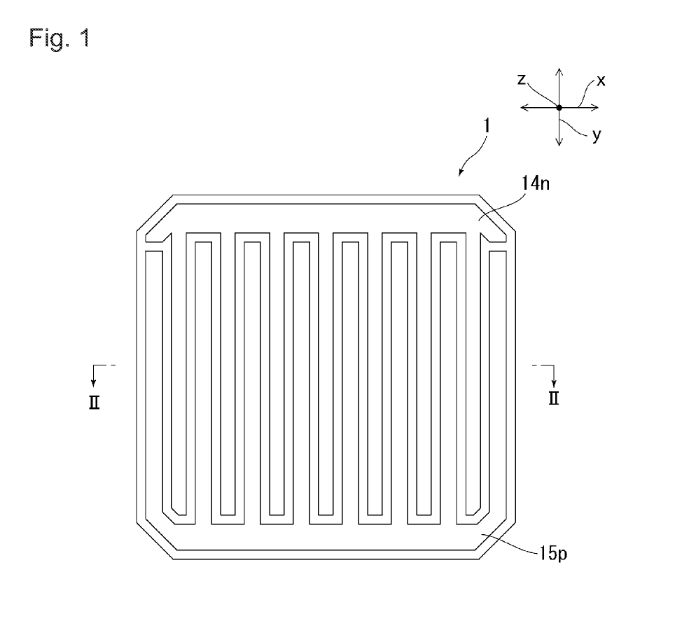

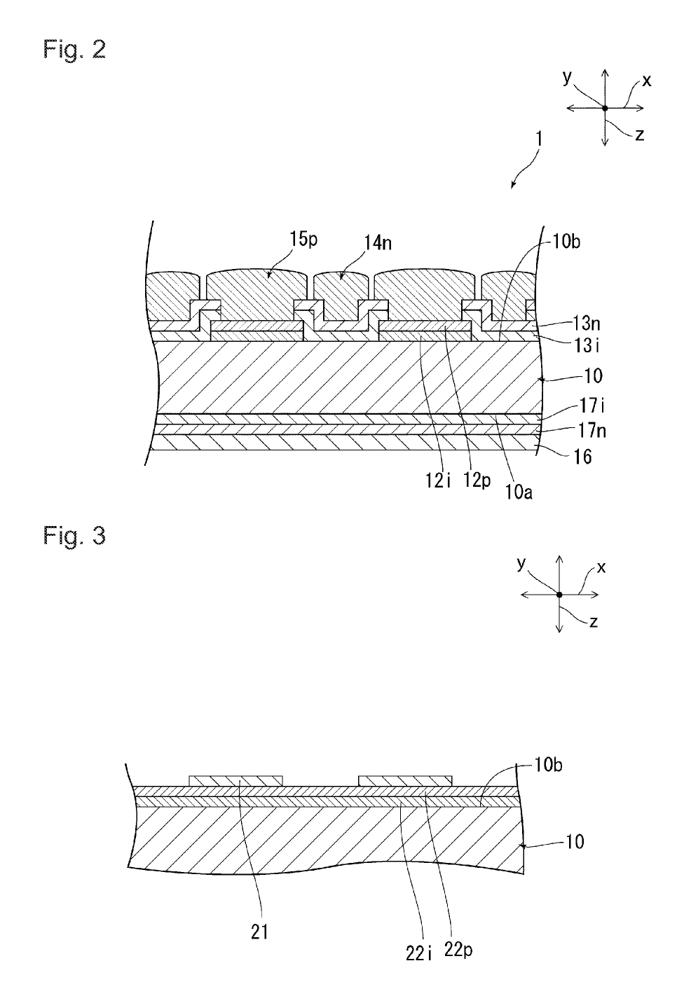

To begin with, a configuration of solar cell 1 as a semiconductor device manufactured in an embodiment is described with reference to FIGS. 1 and 2.

As illustrated in FIG. 2, solar cell 1 includes substrate 10 made of a semiconductor material. Substrate 10 may be made of, for example, crystalline silicon or the like. This embodiment is described for an example in which substrate 10 is made of n-type crystalline silicon.

Substantially-intrinsic i-type semiconductor layer 17i, n-type semiconductor layer 17n having the same conductivity type as substrate 10, and anti-reflection layer 16 also functioning as a protection film are formed in this order on principal surface (light receiving surface) 10a of substrate 10. I-type semiconductor layer 17i may be made of, for example, substantially-intrinsic i-type amorphous silicon or the like. I-type semiconductor layer 17i preferably has a thickness of about several Å to 250 Å, for example, at which i-type semiconductor layer 17i does not substantially contribute to power generation. N-type semiconductor layer 17n may be made of, for example, n-type amorphous silicon or the like. Anti-reflection layer 16 may be made of, for example, silicon nitride or the like.

N-type semiconductor layer 13n and p-type semiconductor layer 12p are arranged on principal surface (back surface) 10b of substrate 10.

N-type semiconductor layer 13n is arranged on a portion of principal surface 10b. N-type semiconductor layer 13n may be made of, for example, n-type amorphous silicon or the like. Substantially-intrinsic i-type semiconductor layer 13i is arranged between n-type semiconductor layer 13n and principal surface 10b. I-type semiconductor layer 13i may be made of, for example, substantially-intrinsic i-type amorphous silicon or the like. I-type semiconductor layer 13i preferably has a thickness of about several Å to 250 Å, for example, at which i-type semiconductor layer 13i does not substantially contribute to power generation.

P-type semiconductor layer 12p is provided on at least part of a portion of principal surface 10b where n-type semiconductor layer 13n is not provided. These p-type semiconductor layer 12p and n-type semiconductor layer 13n substantially entirely cover principal surface 10b. N-type semiconductor layer 13n has portions arranged right above p-type semiconductor layer 12p. Specifically, end portions of n-type semiconductor layer 13n are arranged right above p-type semiconductor layer 12p.

P-type semiconductor layer 12p may be made of, for example, p-type amorphous silicon containing a p-type dopant such as boron, or the like. Substantially-intrinsic i-type semiconductor layer 12i is arranged between p-type semiconductor layer 12p and principal surface 10b. I-type semiconductor layer 12i may be made of, for example, substantially-intrinsic i-type amorphous silicon or the like. I-type semiconductor layer 12i preferably has a thickness of about several A to 250 Å, for example, at which i-type semiconductor layer 12i does not substantially contribute to power generation.

N-side electrode 14n is arranged on n-type semiconductor layer 13n. On the other hand, p-side electrode 15p is arranged on p-type semiconductor layer 12p. N-side electrode 14n and p-side electrode 15p are each formed in a comb-like shape.

Electrodes 14n, 15p maybe each made of at least one kind of metal such for example as Ag, Cu, Au, Pt, Ni or Sn. Electrodes 14n, 15p may be each formed of a single conductive layer or formed of a laminate including multiple conductive layers.

### (Method of Manufacturing Solar Cell 1)

Next, an example of a method of manufacturing solar cell 1 is described mainly with reference to FIGS. 3 to 6.

As illustrated in FIG. 3, i-type semiconductor layer 22i for forming i-type semiconductor layer 12i and p-type semiconductor layer 22p for forming p-type semiconductor layer 12p are formed in this order on principal surface 10b of substrate 10 (p-type semiconductor layer formation process). Semiconductor layers 22i, 22p may be each formed by using a method such for example as a CVD (chemical vapor deposition) method or a sputtering method.

Next, mask 21 is formed on p-type semiconductor layer 22p in such a manner as to cover portions where semiconductor layers 12i, 12p are to be formed. Mask 21 may be made of, for example, a resist material or the like.

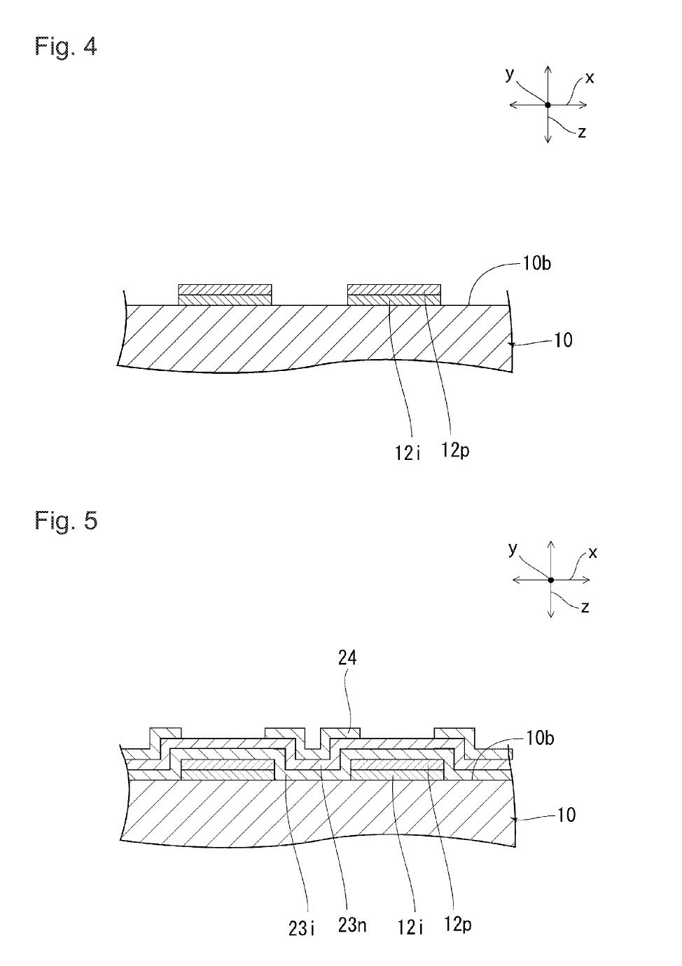

Subsequently, semiconductor layers 22i, 22p are etched withmask 21, and thereby the portions of semiconductor layers 22i, 22p not covered with mask 21 are removed. As a result, semiconductor layers 12i, 12p illustrated in FIG. 4 are formed.

The etching of semiconductor layers 22i, 22p may be favorably performed by using, for example, fluoro-nitric acid (HF—HNO₃), a mixed acid of fluoro-nitric acid and acetic acid (HF—HNO—CH₃COOH), or a mixed acid of fluoro-nitric acid and hydrogen peroxide (HF—HNO—H₂O₂); or instead, any of inorganic alkalis such as sodium hydroxide (NaOH) and potassium hydroxide (KOH), any of organic alkalis such as TMAH (tetramethyl-ammonium), a mixture of ammonia and hydrogen fluoride (NH₃—HF), a mixture of hydrogen fluoride and ozone(HF—O₃), phosphorus oxide (H₃PO₄), or the like.

Next, as illustrated in FIG. 5, i-type semiconductor layer 23i for forming i-type semiconductor layer 13i and n-type semiconductor layer 23n for forming n-type semiconductor layer 13n are formed in this order on principal surface 10b of substrate 10 and also on p-type semiconductor layer 12p. Semiconductor layers 23i, 23n may be each formed by, for example, a CVD method, a sputtering method or the like.

Next, mask 24 is formed on n-type semiconductor layer 23n in such a manner as not to cover at least part of a portion of n-type semiconductor layer 23n below which p-type semiconductor layer 12p is provided. Mask 24 may be made of, for example, a resist material.

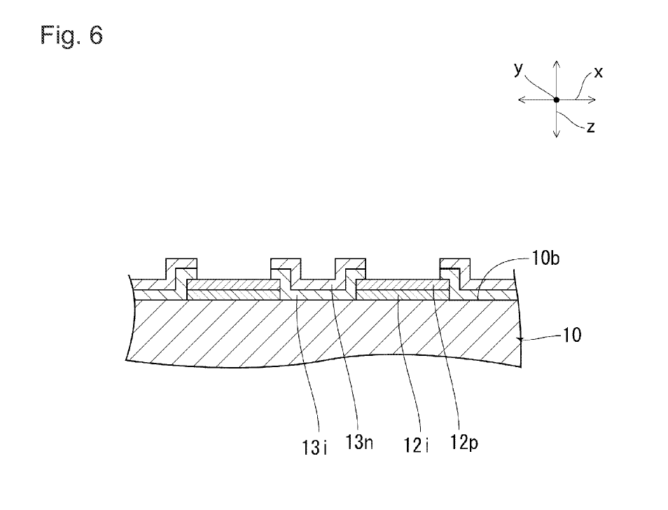

Thereafter, the at least part of the portion of n-type semiconductor layer 23n located above p-type semiconductor layer 12p is removed by etching with an alkaline etchant withmask 24. With this treatment, as illustrated in FIG. 6, i-type semiconductor layer 13i is formed from i-type semiconductor layer 23i, n-type semiconductor layer 13n is formed from n-type semiconductor layer 23n, and p-type semiconductor layer 12p is exposed.

Here, p-type semiconductor layer 12p containing the p-type dopant such as boron has a lower etch rate with an alkaline etchant than n-type semiconductor layer 23n and i-type semiconductor layer 23i. For this reason, the at least part of the portions of n-type semiconductor layer 23n and i-type semiconductor layer 23i located above p-type semiconductor layer 12p can be selectively removed with p-type semiconductor layer 12p kept remaining.

An alkaline etchant preferably used is, for example, an aqueous solution of an alkali metal hydroxide such as a calcium hydroxide solution.

Thereafter, p-side electrode 15p is formed on p-type semiconductor layer 12p and n-side electrode 14n is formed on n-type semiconductor layer 13n. Thus, solar cell 1 is completed. Electrodes 14n, 15p maybe formed, for example, by a plating method, a CVD method, a sputtering method, a conductive paste coating method, or the like.

Here, timings for forming semiconductor layers 17i, 17n and anti-reflection layer 16 are not particularly limited. For example, semiconductor layers 17i, 17n may be formed in the same processes as those for semiconductor layers 23i, 23n.

Meanwhile, as for a solar cell in a configuration where a p-type semiconductor layer and an n-type semiconductor layer are arranged in the order reverse to the configuration of this embodiment, that is, portions of the p-type semiconductor layer are located above the n-type semiconductor layer, the manufacturing requires formation of the n-type semiconductor layer, etching of the n-type semiconductor layer, formation of the p-type semiconductor layer, and etching of the p-type semiconductor layer. Here, note that the n-type semiconductor layer has a higher etch rate with an alkaline etchant than the p-type semiconductor layer. For this reason, when the portions of the p-type semiconductor layer located above the n-type semiconductor layer are surely removed, even the n-type semiconductor layer is etched and removed. In other words, it is difficult to selectively remove the p-type semiconductor layer by etching with an alkaline etchant. As a countermeasure of this, it is necessary to provide an etching stop layer between the n-type semiconductor layer and the p-type semiconductor layer, the etching stop layer made of, for example, silicon nitride or the like, and having a lower etch rate with the alkaline etchant than the p-type semiconductor layer. Accordingly, two etching processes, that is, the processes of etching the p-type semiconductor layer and etching the etching stop layer are needed to expose the n-type semiconductor layer located below the p-type semiconductor layer. In addition, it is necessary to prepare an additional etchant, which is capable of etching an insulating layer while leaving the n-type semiconductor layer unetched. Moreover, a process of forming the insulating layer is needed. Hence, the solar cell manufacturing processes are complicated.

In contrast, in this embodiment, p-type semiconductor layer 22p having a relatively low etch rate with an alkaline etchant is provided below n-type semiconductor layer 23n having a relatively high etch rate with an alkaline etchant. Thus, n-type semiconductor layer 23n can be removed selectively by the alkaline etchant. For this reason, the process of forming the insulating layer on p-type semiconductor layer 12p is unnecessary, and it is sufficient to perform only a single process of etching n-type semiconductor layer 23n in order to expose p-type semiconductor layer 12p. Moreover, this embodiment does not necessarily need an etchant capable of etching the insulating layer while leaving the semiconductor layer unetched. Consequently, solar cell 1 can be manufactured easily with a smaller number of processes.

It should be noted that, although the present embodiment is described hereinabove by taking the solar cell as an example of a semiconductor device, the invention should not be limited to this. A semiconductor device according to the embodiment may be any semiconductor device other than a solar cell. A method of manufacturing a semiconductor device according to the embodiment may be a method of manufacturing a semiconductor device other than a solar cell.

The invention includes other embodiments in addition to the above-described embodiments without departing from the spirit of the invention. The embodiments are to be considered in all respects as illustrative, and not restrictive. The scope of the invention is indicated by the appended claims rather than by the foregoing description. Hence, all configurations including the meaning and range within equivalent arrangements of the claims are intended to be embraced in the invention.

1. A method of manufacturing a solar cell, comprising:
forming a p-type semiconductor layer on a portion of one principal surface of a substrate made of a semiconductor material;
forming an n-type semiconductor layer on the one principal surface of the substrate and also on the p-type semiconductor layer;
etching at least part of a portion of the n-type semiconductor layer located above the p-type semiconductor layer by using an alkaline etchant; and
forming a p-side electrode on the p-type semiconductor layer and forming an n-side electrode on the n-type semiconductor layer.

2. The method of manufacturing a solar cell according to claim 1, wherein
an aqueous solution of an alkali metal hydroxide is used as the alkaline etchant.

3. The method of manufacturing a solar cell according to claim 2, wherein
an aqueous solution of an alkali metal hydroxide is used as the alkaline etchant.

4. The method of manufacturing a solar cell according to claim 1, wherein
forming of the p-type semiconductor layer includes etching a portion of the p-type semiconductor layer formed on the one principal surface of the substrate.

5. The method of manufacturing a solar cell according to claim 2, wherein
forming of the p-type semiconductor layer includes etching a portion of the p-type semiconductor layer formed on the one principal surface of the substrate.

6. The method of manufacturing a solar cell according to claim 4, wherein
the etching of the p-type semiconductor layer is performed by using fluoro-nitric acid.

7. The method of manufacturing a solar cell according to claim 1, wherein
the p-type semiconductor layer has a lower etch rate with the alkaline etchant than n-type semiconductor layer.
